(19) United States
(12) Patent Application Publication
(10) Pub. No.: US 2010/0119073 A1
(43) Pub. Date: May 13, 2010

(54) METHOD AND AN APPARATUS FOR PROCESSING AN AUDIO SIGNAL

(75) Inventors: Hyen O Oh, Seoul (KR); Yang Won Jung, Seoul (KR)

Correspondence Address: BIRCH STEWART KOLASCH & BIRCH, PO BOX 747, FALLS CHURCH, VA, 22040-0747, US

(73) Assignee: LG Electronics, INC., Seoul (KR)

(21) Appl. No.: 12/527,153

(22) PCT Filed: Feb. 13, 2008
(86) PCT No.: PCT/KR08/00837

§ 371 Date: Aug. 13, 2009

Related U.S. Application Data
(60) Provisional application No. 60/889,715, filed on Feb. 13, 2007.
(60) Provisional application No. 61/024,562, filed on Jan. 30, 2008.

(51) Int. Cl. H03F 3/68

(52) U.S. Cl. 381/28

(57) ABSTRACT

Disclosed is a method of processing an audio signal, including obtaining ratio information between a main signal and a sub-signal and gain range information of an object and modifying parameter information including at least one of an object parameter and a control parameter based on the ratio information and the gain range information. Disclosed is a method of processing an audio signal, including generating ratio information using object information, generating gain range information of an object using the ratio information, and modifying parameter information including at least one of an object parameter and a control parameter based on the gain range information.

### TECHNICAL FIELD

The present invention relates to an apparatus for processing an audio signal and method thereof. Although the present invention is suitable for a wide scope of applications, it is particularly suitable for processing an audio signal received via a digital medium, a broadcast signal or the like.

### BACKGROUND ART

Generally, in the process for downmixing a plurality of objects into a mono or stereo signal, parameters are extracted from each object signal. Such parameters are used by a decoder. And, panning and gain of each of the objects are controllable by a selection made by a user.

### DISCLOSURE OF THE INVENTION

### Technical Problem

However, in order to control each object signal, sources contained in downmix should be appropriately positioned or panned.

Moreover, in order to provide backward compatibility by channel-oriented decoding scheme, an object parameter should be flexibly converted to a multi-channel parameter for upmixing.

### Technical Solution

Accordingly, the present invention is directed to an apparatus for processing an audio signal and method thereof that substantially obviate one or more of the problems due to limitations and disadvantages of the related art.

An object of the present invention is to provide an apparatus for processing an audio signal and method thereof, by which gain and panning of an object can be unlimitedly controlled.

Another object of the present invention is to provide an apparatus for processing an audio signal and method thereof, by which gain and panning of an object can be controlled based on a selection made by a user.

A further object of the present invention is to provide an apparatus for processing an audio signal and method thereof, by which gain and panning of an object are be controlled based on a selection made by a user within a predetermined limited range.

### ADVANTAGEOUS EFFECTS

Accordingly, the present invention provides the following effects or advantages.

First of all, it is able to unlimitedly control gain and panning of object.

Secondly, it is able to control gain and panning of object based on a selection made by a user.

Thirdly, in case of adjusting a gain of object, it is able to prevent audio quality from being distorted according to a gain adjustment by providing a gain range for the gain adjustment.

### DESCRIPTION OF DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a block diagram of an audio signal processing apparatus according to an embodiment of the present invention;

FIG. 2 is an exemplary detailed block diagram of an information generating unit of an audio signal processing apparatus according to an embodiment of the present invention;

FIG. 3 is a flowchart for an audio signal processing method according to one embodiment of the present invention;

FIG. 4 is another exemplary detailed block diagram of an information generating unit of an audio signal processing apparatus according to an embodiment of the present invention; and

FIG. 5 is a flowchart for an audio signal processing method according to another embodiment of the present invention.

### BEST MODE

Additional features and advantages of the invention will be set forth in the description which follows, and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, a method of processing an audio signal according to the present invention includes obtaining ratio information between a main signal and a sub-signal and gain range information of an object and modifying parameter information including at least one of an object parameter and a control parameter based on the ratio information and the gain range information.

According to the present invention, the ratio information is obtained from an audio signal bitstream.

According to the present invention, the method further includes obtaining transmission flag information indicating whether the ratio information and the gain range information are transmitted, wherein the ratio information and the gain range information are obtained from the audio signal bitstream based on the transmission flag information.

According to the present invention, the method further includes obtaining relational flag information indicating whether an object signal corresponds to a relational signal, wherein the obtaining the transmission flag information is executed based on the relational flag information.

According to the present invention, the relational flag information indicates whether an object signal corresponds to a relational signal per an object.

According to the present invention, the method further includes receiving frequency resolution information, wherein the modifying the parameter information is executed based on the frequency resolution information.

According to the present invention, the gain range information includes at least one of an absolute gain value for a specific object and a relative gain difference value between objects.

According to the present invention, the gain range information varies per time per subband.

According to the present invention, the method includes displaying the gain range information and receiving user control information for per-object gain adjustment, wherein the control parameter is generated based on the user control information.

According to the present invention, the method further includes generating multi-channel information using the modified parameter information.

According to the present invention, the method further includes receiving downmix information including the main signal and the sub-signal and generating a multi-channel signal using the downmix information and the multi-channel information.

According to the present invention, the method further includes receiving mix information including the control parameter, wherein the mix information is generated based on at least one of object position information, object gain information and playback configuration information.

According to the present invention, the audio signal is received via a broadcast signal.

According to the present invention, the audio signal is received via a digital medium.

To further achieve these and other advantages and in accordance with the purpose of the present invention,

a computer-readable recording medium includes a program recorded thereon, in which the program executes obtaining ratio information between a main signal and a sub-signal and gain range information of an object and modifying parameter information including at least one of an object parameter and a control parameter based on the ratio information and the gain range information.

To further achieve these and other advantages and in accordance with the purpose of the present invention, an apparatus for processing an audio signal includes an information transceiving part obtaining ratio information between a main signal and a sub-signal and gain range information of an object and an information modifying part modifying parameter information including at least one of an object parameter and a control parameter based on the ratio information and the gain range information.

To further achieve these and other advantages and in accordance with the purpose of the present invention, a method of processing an audio signal includes obtaining object information including first level information, obtaining ratio information between a main signal and a sub-signal and gain range information of an object, and modifying parameter information including at least one of an object parameter and a control parameter based on one of the first level information and second level information, wherein the second level information is generated using the ratio information and the gain range information.

According to the present invention, the method further includes generating multi-channel information using the modified parameter information.

To further achieve these and other advantages and in accordance with the purpose of the present invention, a computer-readable recording medium includes a program recorded thereon, in which the program executes obtaining object information including first level information, obtaining ratio information between a main signal and a sub-signal and gain range information of an object, and modifying parameter information including at least one of an object parameter and a control parameter based on one of the first level information and second level information, wherein the second level information is generated using the ratio information and the gain range information.

To further achieve these and other advantages and in accordance with the purpose of the present invention, an apparatus for processing an audio signal includes an information transceiving part obtaining object information including first level information, the information transceiving part obtaining ratio information between a main signal and a sub-signal and gain range information of an object and an information modifying part modifying parameter information including at least one of an object parameter and a control parameter based on one of the first level information and second level information, wherein the second level information is generated using the ratio information and the gain range information.

To further achieve these and other advantages and in accordance with the purpose of the present invention, a method of processing an audio signal includes generating ratio information using object information, generating gain range information of an object using the ratio information, and modifying parameter information including at least one of an object parameter and a control parameter based on the gain range information.

According to the present invention, the generating the ratio information is executed using object level information of object signals.

According to the present invention, the generating the ratio information is executed using a ratio between object level information of a specific object signal and object level information of a different object signal.

According to the present invention, the object level information of the different object signal is a sum of object level informations of at least two different object signals.

According to the present invention, the generating the gain range information is executed using at least one of default guide information, user guide information and encoder guide information.

According to the present invention, the gain range information includes at least one of an absolute gain value for a specific object and a relative gain difference value between objects.

According to the present invention, the gain range information varies per time per subband.

According to the present invention, the method further includes receiving downmix information including a main signal and a sub-signal, wherein the ratio information includes a relative ratio between the main signal and the sub-signal.

According to the present invention, the method further includes generating multi-channel information using the modified parameter information.

According to the present invention, the method further includes receiving mix information including the control parameter, wherein the mix information is generated based on at least one of object position information, object gain information and playback configuration information.

According to the present invention, the audio signal is received via a broadcast signal.

According to the present invention, the audio signal is received via a digital medium.

To further achieve these and other advantages and in accordance with the purpose of the present invention, a computer-readable recording medium includes a program recorded thereon, in which the program executes generating ratio information using object information, generating gain range information of an object using the ratio information, and modifying parameter information including at least one of an object parameter and a control parameter based on the gain range information.

To further achieve these and other advantages and in accordance with the purpose of the present invention, an apparatus for processing an audio signal includes an information generating part generating ratio information using object information, the information generating part generating gain range information of an object using the ratio information and an information modifying part modifying parameter information including at least one of an object parameter and a control parameter based on the gain range information.

It is to be understood that both the foregoing general description and the following detailed description are exemplary and explanatory and are intended to provide further explanation of the invention as claimed.

### MODE FOR INVENTION

Reference will now be made in detail to the preferred embodiments of the present invention, examples of which are illustrated in the accompanying drawings.

In this disclosure, information is a terminology that includes values, parameters, coefficients, elements and the like and can be construed as a different meaning case by case.

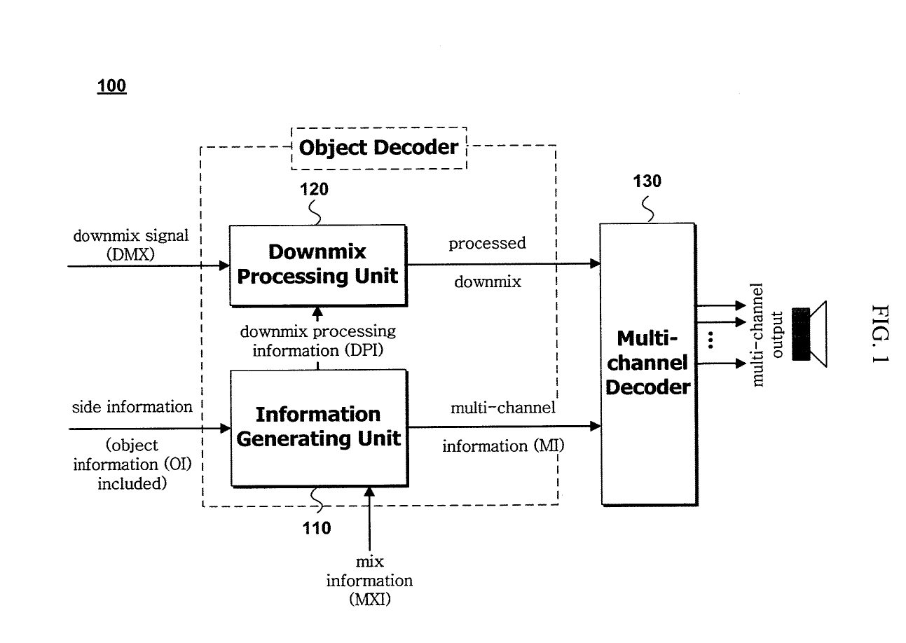

FIG. 1 is a block diagram of an audio signal processing apparatus according to an embodiment of the present invention. Referring to FIG. 1, an audio signal processing apparatus 100 according to an embodiment of the present invention includes an information generating unit 110, a downmix processing unit 120, and a multi-channel decoder 130.

The information generating unit 110 receives side information containing object information (On and the like via an audio signal bitstream and also receives mix information (MXI) via a user interface. In this case, the object information (OI) is information for objects contained in a downmix signal and can include object level information, object correlation information and the like. The object information (OI) can contain an object parameter (OP) that is a parameter indicating an object characteristic. Meanwhile, the mix information (MXI) is information generated based on object position information, object gain information, playback configuration information and the like. In particular, the object position information is information inputted by a user to control a position or panning of each object and the object gain information is information inputted by a user to control a gain of each object. The playback configuration information is information containing the number of speakers, speaker positions, ambient information (virtual positions of speakers) and the like. And, the playback configuration information can be inputted by a user, stored in advance or received from another device. The mix information (MXI) can contain a control parameter (CP). In particular, the control parameter (CP) may be a parameter corresponding to the object gain information, to which the present invention is not limited.

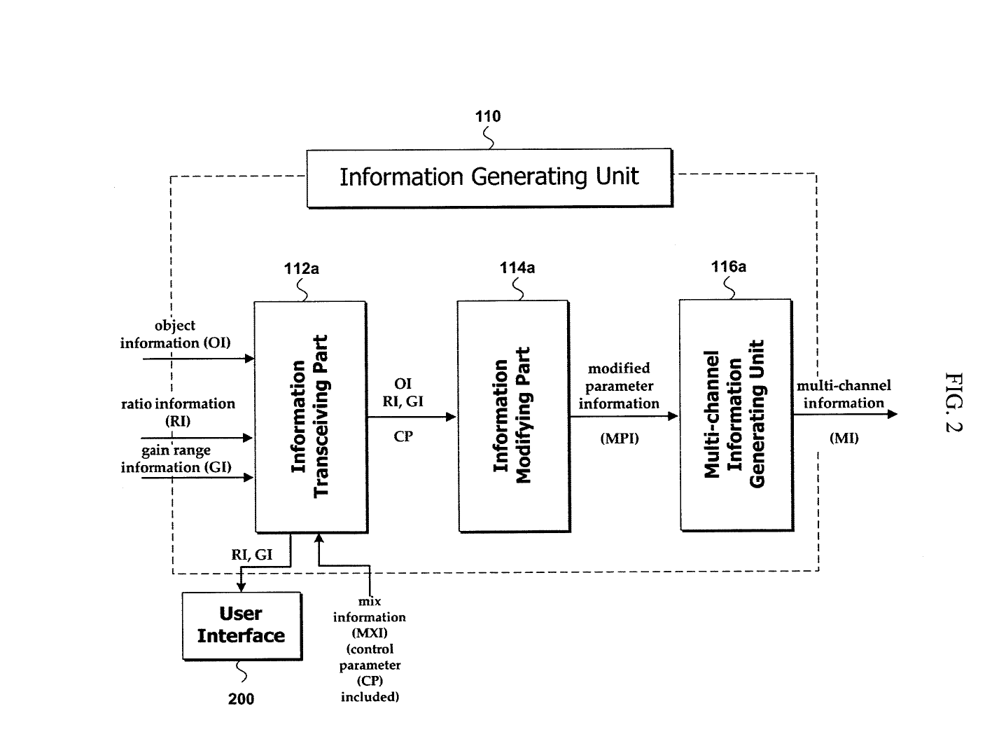

Meanwhile, the information generating unit 110 receives ratio information (RI), gain range information (GI) and the like from a bitstream or generates them by itself. Details of the ratio information (RI), the gain range information (GI) and the like will be described with reference to FIGS. 2 to 5 later. The information generating unit 110 generates modified parameter information (MPI) by modifying parameter information (PI) using the ratio information (RI) and the gain range information (GI), and then generates multi-channel information (MI) using the modified parameter information (MPI). In this case, the multi-channel information (MI) is information to upmix a downmix signal (DMX) and can contain channel level information, channel correlation information and the like. This will be described in detail with reference to FIGS. 2 to 5 later.

The information generating unit 110 is able to generate downmix processing information (DPI) using the modified parameter information (MPI) and the like. If the downmix processing unit 120 is to adjust not an object gain but an object panning, the information generating unit 110 is able to generate the downmix processing information (DPI) using non-modified parameter information (PI) instead of the modified parameter information (MPI).

The downmix processing unit 120 receives downmix information (hereinafter named a downmix signal (DMX)) and then processes the downmix signal (DMX) using downmix processing information (DPI). The downmix processing unit 120 is able to process a downmix signal (DMX) to adjust a panning or gain of object.

The multi-channel decoder 130 receives a processed downmix and generates a multi-channel signal by upmixing a processed downmix signal using multi-channel information (MI).

A process for generating multi-channel information (MI), in which the information generating unit 110 receives ratio information (RI), gain range information (GI) and the like from a bitstream or generates them by itself, using the received or generated information is explained in detail with reference to FIGS. 2 to 5 as follows.

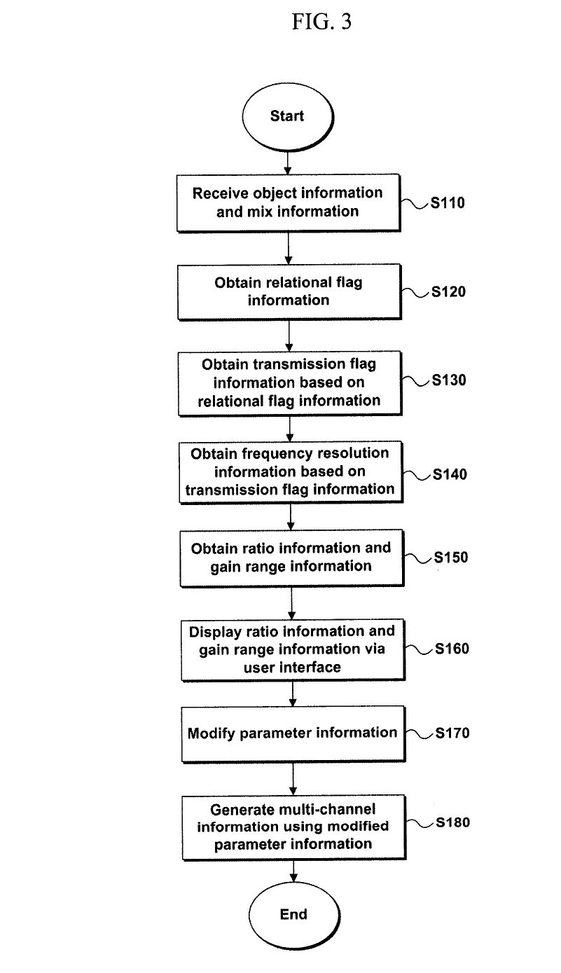

FIG. 2 is an exemplary detailed block diagram of an information generating unit of an audio signal processing apparatus according to an embodiment of the present invention, and FIG. 3 is a flowchart for an audio signal processing method according to one embodiment of the present invention. FIG. 2 and FIG. 3 show an embodiment of a scheme for receiving ratio information (RI) from a bitstream. Referring to FIG. 2, the information generating unit 110 includes an information transceiving part 112a, an information modifying part 114a, and a multi-channel information generating part 116a. Elements and steps are explained in detail with reference to FIG. 2 and FIG. 3 as follows.

First of all, the information transceiving part 112a obtains object information (OI) containing an object parameter (OP) from an audio signal bitstream and also obtains mix information (MXI) containing a control parameter (CP) from a user interface or the like [S110]. In this step, the object information (OI) may be identical to the former object information explained with reference to FIG. 1. In case that object level information is contained in the object information and then transmitted, the transmitted object level information shall be named first object level information (OL1).

And, the information transceiving part 112a obtains relational flag information from the audio signal bitstream [S120].

First relational flag information of the relational flag information can be contained in a bitstream. The meaning of the first relational flag information indicates whether each object signal contained in a downmix signal is independent or whether there exists at least one signal corresponding to a relational signal. For instance, if the first relational flag information is set to 0, it can be set to mean that every object signal is an independent signal. If the first relational flag information is set to 1, it can be set to mean that there exists at least one object signal corresponding to a relational signal. In this case, in adjusting an object level, the relational signal is a signal that may cause degradation of audio quality if a relative level to another object signal is greater or smaller than a predetermined level.

Meanwhile, according to the first relational flag information, if there exists at least one object signal corresponding to a relation signal (e.g., if the first relational flag information is set to 1), it is able to extract second relational flag information indicating whether a corresponding object corresponds to a relational signal per object. On the contrary, if any object signal corresponding to a relational signal does not exist at all (e.g., if the first relational flag information is set to 0), it is unnecessary to extract second relational flag information indicating whether a corresponding object corresponds to a relational signal per object.

According to the obtained second relational flag information, it is able to know whether the corresponding object signal corresponds to the relational signal. For instance, if second relational flag information is set to 0, it is able to set to mean that a corresponding object signal does not correspond to a relational signal. If second relational flag information is set to 1, it is able to set to mean that a corresponding object signal corresponds to a relational signal. This does not restrict various implements of the present invention.

Thus, based on the relational flag information obtained in the step S120, transmission flag information indicating whether ratio information (RI) and gain rang information (GI) are transmitted is obtained [S130]. In particular, as a result of referring to the second relational flag information, if the corresponding object corresponds to the relational signal (e.g., if the second relation flag information is set to 1), it is able to extract transmission flag information for the corresponding object.

Based on the transmission flag information obtained in the step S130, it is able to know whether the ratio information 9RI) and the gain range information (GI) for the corresponding object are transmitted. For instance, if the transmission flag information is set to 0, it means that the ratio information (RI) and the gain range information (GI) are not transmitted. If the transmission flag information is set to 1, it may mean that the ratio information (RI) and the gain range information (GI) are transmitted.

Alternatively, the present invention can implement an embodiment that transmission flag information is contained in a bitstream only instead of a bitstream containing both of the first relational flag information and the second relational flag information. And, the present invention enables various implements thereof.

Subsequently, as a result of referring to the transmission flag information obtained in the step s130, if the ratio information and the gain range information are transmitted (e.g., if the transmission flag information is set to 1), frequency resolution information indicating resolution of frequency, in which the gain rage information (GI) exists, is obtained [S140]. For instance, if the frequency resolution information is ‘1’, it can be set to mean that the resolution of frequency, in which the gain rage information (GI) exists, is ‘28’. If the frequency resolution information is ‘2’, it can be set to mean that the resolution of frequency, in which the gain rage information (GI) exists, is ‘20’. And, the present invention enables various implements thereof.

As a result of referring to the transmission flag information obtained in the step s130, if the ratio information (RI) and the gain range information (GI) are transmitted (e.g., if the transmission flag information is set to 1), the ratio information (RI) and the gain range information (GI) are obtained [S150]. In this case, the ratio information (RI) is information corresponding to whether a corresponding object signal is close to a main signal or a sub-signal. In particular, the ratio information can include a relative ratio between the main signal and the sub-signal. For instance, a main signal corresponds to a speech signal and a sub-signal corresponds to a noise signal. For another instance, a main signal corresponds to a main vocal signal and a sub-signal corresponds to a back-chorus signal. And, the present invention enables various implements thereof. For instance, if ratio information is set to ‘0’, it can be set to mean that a corresponding object signal is very close to a sub-signal. If ratio information is set to ‘1’, it can be set to mean that a corresponding object signal is close to a sub-signal. If ratio information is set to ‘2’, it can be set to mean that a corresponding object signal is close to a main signal. If ratio information is set to ‘3’, it can be set to mean that a corresponding object signal is very close to a main signal. And, the present invention enables various implements thereof.

Besides, the gain range information (GI) can contain a range for gain adjustment of object. In this case, the range can include a limited value such as an upper limit, a lower limit and the like. The limited value may correspond to an absolute gain value for a specific object or a relative gain difference value between objects. In case that the limited value corresponds to the absolute gain value, a gain adjustment range of a vocal signal may become 10 dB or below for example. If the limited value corresponds to the relative gain difference value, a gain adjustment value of a vocal signal may become 10 dB or below with reference to a piano signal. In this case, it is able to emphasize the vocal signal by 10 dB only. Alternatively, it is able to emphasize the vocal signal by 5 dB while suppressing the piano signal by 5 dB. This gain range information (GI) may be a value that is constant on time and frequency bands but an be variable per time per subband.

Moreover, the gain range information (GI) may correspond to relative gain adjustment interworking information. In case that a specific object is emphasized or suppressed, the relative gain adjustment interworking information is information indicating whether another object needs to be emphasized or suppressed correspondingly. For instance, in case of a vocal signal and a back-chorus signal, if the vocal signal is emphasized by 10 dB, the back-chorus signal needs to be emphasized by 5-15 dB to reduce distortion of audio quality.

In the step S150, it is able to extract the ratio information (RI) per parameter per object and it is also able to extract the gain range information (GI) per object according to frequency resolution. And, the present invention enables various implements thereof.

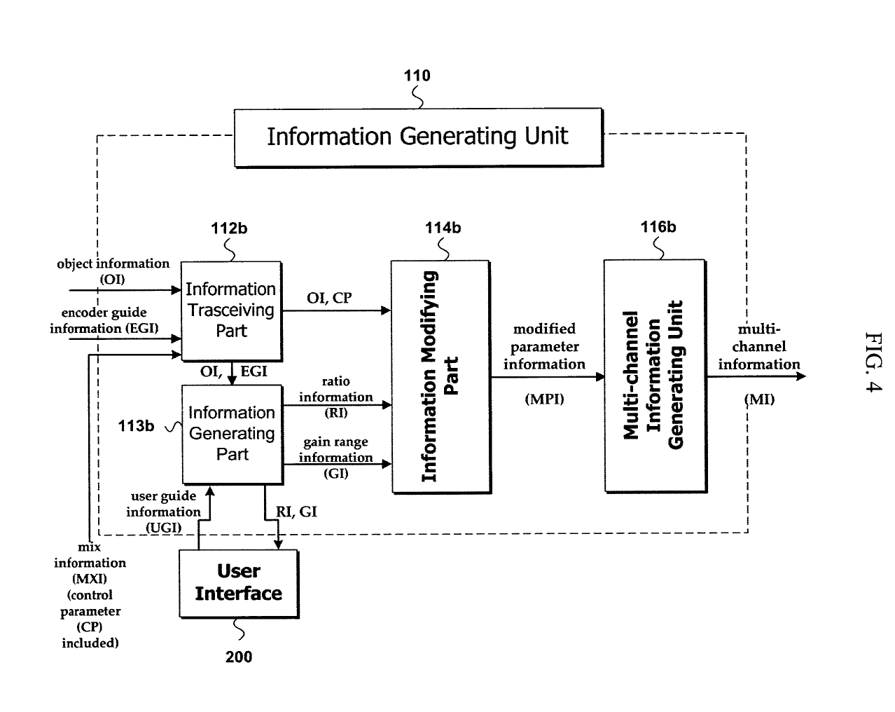

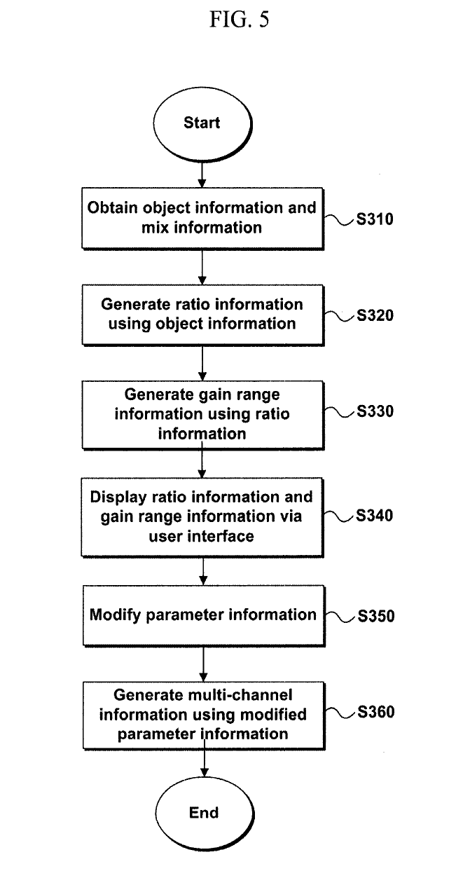

Meanwhile, in the step S150, ratio information (RI) is extracted from an audio signal bitstream only and gain range information (GI) is generated by itself without being extracted. In generating the gain range information (GI), it is able to use a method that will be explained with reference to FIG. 4 and FIG. 5.

The information transceiving part 112a is able to display the ratio information (RI) and the gain range information (GI) obtained in the step S150 via the user interface 200 [S160]. For instance, a message indicating whether a vocal signal is a relational signal to another signal, a message indicating that audio quality may be distorted in case of adjusting a gain of a vocal signal by 10 dB or more and the like can be displayed on a screen to be viewed by a user. After the user has confirmed such a message, it is able to input user control information about per-object gain adjustment via the user interface 200. In this case, it is able to force the user control information to be adjusted within a limited value even if a value (e.g., 20 dB) exceeding the limited value (10 dB) of object signal is inputted. Although the limited value is exceeded, it is able to reflect the user control information (20 dB) as it is. In this case, the mix information (MXI) received in the step S110 may be generated based on such user control information.

The information modifying part 114a modifies parameter information (PI) containing at least one selected from the object parameter (OP) and the control parameter (CP) obtained in the step S110 using the ratio information (RI) and the gain range information (GI) obtained in the step S150 [S170]. In particular, after the gain range information (GI) has been modified using the mix information (MXI) and the ratio information (RI), it is able to generate modified parameter information (MPI) by applying the modified gain range information to the object parameter (OP). And, the present invention enables various implements thereof. The step S170 can be executed based on the frequency resolution information extracted in the step S140. In particular, according to the frequency resolution information extracted in the step S140, gain range information corresponding to each frequency band, the corresponding gain range information is mapped to entire frequency band, the step S180 is then executed. Meanwhile, the modified parameter information (MPI) can contain second object level information (OL2) different from the first object level information (OL1) received in the step S110.

The multi-channel information generating part 116a generates multi-channel information (MI) [S180]. In this case, it is able to generate multi-channel information (MI) using the first object level information (OL1) transmitted in the step S110. alternatively, it is able to generate multi-channel information (MI) using the second object level information (OL2) of the modified parameter information (MPI) generated in the step S170. Of course, the case of using the first object level information (OL1) is a case that a guide is not applied in level adjustment.

FIG. 4 is another exemplary detailed block diagram of an information generating unit of an audio signal processing apparatus according to an embodiment of the present invention, and FIG. 5 is a flowchart for an audio signal processing method according to another embodiment of the present invention. FIG. 4 and FIG. 5 relate to an embodiment that ratio information (RI) is generated by a decoder itself. Referring to FIG. 4, an information generating unit 110 includes an information transceiving part 112b, an information generating part 113b, an information modifying part 114b, and a multi-channel information generating part 116b. Elements and steps are explained in detail with reference to FIG. 4 and FIG. 5 as follows.

First of all, the information transceiving part 112b receives object information (OI) containing an object parameter (OP) from an audio signal bitstream and also receives mix information (MXI) containing a control parameter (CP) from a user interface or the like [S310]. Moreover, the information transceiving part 112b can receive encoder guide information (EGI). In this case, the encoder guide information (EGI) is guide information generated by an encoder, contains a range for gain adjustment of object, and may be information received via an audio signal bitstream.

The information generating part 113b generates ratio information using the object information (OI) received in the step S310 [S320]. In particular, it is able to generate ratio information (RI) using the object level information (OLI) in the object information (OI). In this case, the ratio information (RI) corresponds to a relative ratio between a main signal and a sub-signal or may correspond to a level information ratio to other object signal(s). The level information ratio to other object signal can be defined as follows.

$${OLD}_{ratio} = \frac{{OLD}_{i}}{{OLD}_{k}} \qquad [ Formula 1 ]$$

In Formula 1, OLD₁ indicates object level information of an i^{th} object signal and OLDₖ indicates object level information of other object signal (k≠i).

Meanwhile, if there are at least two other object signals, ratio information may correspond to a level information ratio to all other object signals. This can be defined as Formula 2.

$${OLD}_{ratio} = \frac{{OLD}_{i}}{{OLD}_{1} + … + {OLD}_{k} + … + {OLD}_{N}} \qquad [ Formula 2 ]$$

In Formula 2, OLDᵢ indicates object level information of an ith object signal, ‘N’ indicates a total number of object signals, and k=0˜N (k≠i).

Subsequently, gain range information (GI) is generated using the ratio information (RI) generated in the step S320 [S330]. In this case, the gain range information (GI) can contain a range for gain adjustment of object like the former gain range information (GI) explained with reference to FIG. 2 and FIG. 3. And, the range can include a limited value such as an upper limit, a lower limit and the like. In this case, the limited value may correspond to an absolute gain value for a specific object or a relative gain difference value between objects. This gain range information (GI) may be a value that is constant on time and frequency bands but can be changed per time per subband.

The gain range information (GI) can be generated in various ways using the ratio information (RI). In case that OLDᵣₐₜᵢₒ is very high, it is able to set a gain limit value (G_{gain}) of the gain range information (GI) to a large value. This is because, if OLDᵣₐₜᵢₒ is very high, audio quality distortion can be reduced even if large rendering freedom degree is given. For instance, if OLDᵣₐₜᵢₒ(vocal) of vocal signal has a very high value, a gain limit value G_{gain} for the vocal signal may become 20 dB. If OLDᵣₐₜᵢₒ(vocal) of vocal signal has a high value for a piano signal only, a gain limit value G_{gain}(back chorus) of the vocal signal for the piano signal can be set to a large value.

Meanwhile, in order to generate more precise gain range information (GI), when an encoder generates object level information (OLD), it is able to give specific frequency weighting. For instance, after OLD has been found using a filter in which weighting for emphasizing a specific frequency is given to 0^{th} band corresponding to a lowest frequency band, difference information from OLD found by a general method can be contained as side information. In case of an audio signal or the like, such difference information is utilized in generating gain range information (GI).

Meanwhile, in generating the gain range information (GI) in the step S330, default guide information (DGI), user guide information (UGI), encoder guide information (EGI) and the like are usable. The default guide information (DGI) means guide information preset by a decoder itself, the user guide information (UGI) corresponds to guide information inputted via the user interface 200 and the encoder guide information (EGI) corresponds to guide information, which is generated by an encoder and then extracted from an audio bitstream. In generating gain range information (GI), it is able to refer to default guide information (DGI), user guide information (UGI), encoder guide information (EGI) and the like. For instance, although a gain limit value (G_{gain}) of a specific object can be set to 10 dB based on object level information only. In this case, if user guide information (UGI) is 5 dB, it is able to generate gain range information (GI) by referring to the user guide information (UGI).

Thus, the ratio information (RI) generated in the step S320 and the gain range information (GI) generated in the step S330 can be displayed via the user interface 200 [S340], which is as good as the former step S160.

The information modifying part 114b modifies parameter information (PI) containing at least one of object parameter (OP) and control parameter (CP) [S350], which is as good as the former step S170.

And, the multi-channel information generating part 116b generates multi-channel information (MI) using the modified parameter information (MPI) [S360], which is as good as the former step S190.

### INDUSTRIAL APPLICABILITY

Accordingly, the present invention is applicable to audio signal encoding and decoding.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

What is claimed is:

1. A method of processing an audio signal, comprising:
generating ratio information using object information;
generating gain range information of an object using the ratio information; and
modifying parameter information including at least one of an object parameter and a control parameter based on the gain range information.

2. The method of claim 1, wherein the generating the ratio information is executed using object level information of object signals.

3. The method of claim 2, the generating the ratio information is executed using a ratio between object level information of one object signal and object level information of another object signal.

4. The method of claim 3, wherein the object level information of the another object signal is a sum of object level informations of at least two another object signals.

5. The method of claim 1, wherein the generating the gain range information is executed using at least one of default guide information, user guide information and encoder guide information.

6. The method of claim 1, wherein the gain range information includes at least one of an absolute gain value for a one object and a relative gain difference value between objects.

7. The method of claim 1, wherein the gain range information varies per time per subband.

8. The method of claim 1, further comprising receiving downmix information including a main signal and a sub-signal,
wherein the ratio information includes a relative ratio between the main signal and the sub-signal.

9. The method of claim 1, further comprising generating multi-channel information using the modified parameter information.

10. The method of claim 1, further comprising receiving mix information including the control parameter,
wherein the mix information is generated based on at least one of object position information, object gain information and playback configuration information.

11. The method of claim 1, wherein the audio signal is received via a broadcast signal.

12. The method of claim 1, wherein the audio signal is received via a digital medium.

13. A computer-readable recording medium comprising a program recorded thereon, the program executing:
generating ratio information using object information;
generating gain range information of an object using the ratio information; and
modifying parameter information including at least one of an object parameter and a control parameter based on the gain range information.

14. An apparatus for processing an audio signal, comprising:
an information generating part generating ratio information using object information, the information generating part generating gain range information of an object using the ratio information; and
an information modifying part modifying parameter information including at least one of an object parameter and a control parameter based on the gain range information.
